(19) United States
(12) Patent Application Publication
(10) Pub. No.: US 2026/0011000 A1
(43) Pub. Date: Jan. 8, 2026

(54) MULTI-DIE DEFECT DETECTION USING A NEURAL NETWORK

(71) Applicant: Applied Materials Israel Ltd., Rehovot (IL)

(72) Inventor: Saptarshi ROY, Kolkata (IN)

(21) Appl. No.: 18/764,013

(22) Filed: Jul. 3, 2024

(51) Int. Cl. G06T 7/00

(52) U.S. Cl. CPC G06T 7/001; G06T 2207/20081; G06T 2207/20084; G06T 2207/30148

(57) ABSTRACT

There is provided a system and method of runtime defect detection in a semiconductor specimen. The method includes obtaining a plurality of runtime images acquired for a plurality of dies on the specimen, feeding the plurality of runtime images to a plurality of input channels of a neural network (NN) in an input order, wherein the NN is previously trained in a training phase, and processing, by the NN, the plurality of runtime images simultaneously, to obtain a plurality of defect maps, each corresponding to a respective runtime image and indicating probabilities of defect candidate presence thereof. Each given runtime image is processed as a target image using remaining images in the plurality of runtime images as reference images of the target image, and the defect map of the target image remains invariant, irrespective of changes to the input order.

### TECHNICAL FIELD

The presently disclosed subject matter relates, in general, to the field of examination of a semiconductor specimen, and more specifically, to machine-learning based defect detection on a specimen.

### BACKGROUND

Current demands for high density and performance associated with ultra large-scale integration of fabricated devices require submicron features, increased transistor and circuit speeds, and improved reliability. As semiconductor processes progress, pattern dimensions such as line width, and other types of critical dimensions, are continuously shrunken. Such demands require formation of device features with high precision and uniformity, which, in turn, necessitates careful monitoring of the fabrication process, including automated examination of the devices while they are still in the form of semiconductor wafers.

Examination can be provided by using non-destructive examination tools during or after manufacture of the specimen to be examined. A variety of non-destructive examination tools includes, by way of non-limiting example, scanning electron microscopes, atomic force microscopes, optical inspection tools, etc.

Examination processes can include a plurality of examination steps. The manufacturing process of a semiconductor device can include various procedures such as etching, depositing, planarization, growth such as epitaxial growth, implantation, etc. The examination steps can be performed a multiplicity of times, for example after certain process procedures, and/or after the manufacturing of certain layers, or the like. Additionally, or alternatively, each examination step can be repeated multiple times, for example for different wafer locations, or for the same wafer locations with different examination settings.

During the examination processes at various steps during semiconductor fabrication, examination images are acquired by the examination tools which are processed for the purpose of examination operations such as detecting and classifying defects on specimens, as well as performing metrology related operations.

Effectiveness of examination can be improved by automatization of process(es) such as, for example, defect detection, Automatic Defect Classification (ADC), Automatic Defect Review (ADR), image segmentation, automated metrology-related operations, etc. Automated examination systems ensure that the parts manufactured meet the quality standards expected and provide useful information on adjustments that may be needed to the manufacturing tools, equipment, and/or compositions, depending on the type of defects identified. In some cases, machine learning technologies can be used to assist the automated examination process, so as to promote higher yield.

### SUMMARY

In accordance with certain aspects of the presently disclosed subject matter, there is provided a computerized system of runtime defect detection in a semiconductor specimen, the system comprising a processing circuitry configured to obtain a plurality of runtime images acquired for a plurality of dies on the specimen;

feed the plurality of runtime images to a plurality of input channels of a neural network (NN) in an input order, wherein the NN is previously trained in a training phase; and process, by the NN, the plurality of runtime images simultaneously, to obtain a plurality of defect maps, each corresponding to a respective runtime image and indicating probabilities of defect candidate presence thereof, comprising, for each runtime image: process the runtime image as a target image of a corresponding input channel that receives the runtime image, wherein remaining images in the plurality of runtime images are used as reference images of the target image; and obtain a defect map of the target image which remains invariant, irrespective of changes to the input order.

In addition to the above features, the system according to this aspect of the presently disclosed subject matter can comprise one or more of features (i) to (viii) listed below, in any desired combination or permutation which is technically possible:
(i). The NN comprises a plurality of hidden layers each comprising a plurality of subsets of filters, each subset of filters in a given hidden layer corresponding to a specific input channel and usable for processing a target image or derivatives thereof of the specific input channel. Each subset of filters of the given hidden layer comprises a target filter to be applied to the target image or derivatives thereof, and reference filters to be applied to the reference images or derivatives thereof of the target image. The reference filters have the same values.
(ii). The target filter across the plurality of subsets of filters in the given hidden layer has the same value.
(iii). The changes to the input order include at least one of: switching an order of the reference images, and switching an order of the target image and a reference image.
(iv). The processing circuitry is configured to process the plurality of runtime images by: for each specific input channel of a given hidden layer, applying a given subset of filters corresponding to the specific input channel to the target image or derivatives thereof and the reference images or derivatives thereof, to obtain an output feature map serving as an input feature map of a subsequent hidden layer.
(v) The processing of the plurality of runtime images further comprises providing a background defect map, as part of the output of the NN, indicating probability of defect absence in all of the plurality of dies.
(vi). The plurality of defect maps are further reviewed by a review tool.
(vii). One or more locations of false alarms and/or missed defect of interests (DOIs) identified during review are re-examined, comprising: acquiring, by an inspection tool, one or more new images of the one or more locations, processing the one or more new images by the NN to obtain one or more new defect maps, and performing algorithmic analysis based on the new defect maps with respect to ground truth information of the locations provided by the review tool.
(viii). The NN is a Convolutional Neural Network (CNN).

In accordance with other aspects of the presently disclosed subject matter, there is provided a computerized method of runtime defect detection in a semiconductor specimen, the method comprising: obtaining a plurality of runtime images acquired for a plurality of dies on the specimen; feeding the plurality of runtime images to a plurality of input channels of a neural network (NN) in an input order, wherein the NN is previously trained in a training phase; and processing, by the NN, the plurality of runtime images simultaneously, to obtain a plurality of defect maps, each corresponding to a respective runtime image and indicating probabilities of defect candidate presence thereof, comprising, for each runtime image: processing the runtime image as a target image of a corresponding input channel that receives the runtime image, wherein remaining images in the plurality of runtime images are used as reference images of the target image; and obtaining a defect map of the target image which remains invariant irrespective of changes to the input order.

These aspects of the disclosed subject matter can comprise one or more of features (i) to (viii) listed above with respect to the system, mutatis mutandis, in any desired combination or permutation which is technically possible.

In accordance with other aspects of the presently disclosed subject matter, there is provided a computerized system of training a neural network (NN) usable for defect detection in a semiconductor specimen, the system comprising a processing circuitry configured to obtain a plurality of training images acquired for a plurality of dies of a training specimen, each training image associated with a ground truth defect map indicative of defect candidate distribution in the training image; feed the plurality of training images to a plurality of input channels of the NN in an input order; process the plurality of training images by the NN simultaneously, to obtain, for each given training image, a predicted defect map indicating probabilities of defect candidate presence in the given training image; optimize the NN using a loss function based on the predicted defect map and the ground truth defect map associated with the given training image; and repeat the feeding, processing, and optimizing until a criterion is met, thereby obtaining a trained NN usable to provide, for a plurality of runtime images, a plurality of defect maps invariant to changes to the input order of the plurality of runtime images to the trained NN.

In addition to the above features, the system according to this aspect of the presently disclosed subject matter can comprise one or more of features (ix) to (xiv) listed below, in any desired combination or permutation which is technically possible:
(ix). The NN comprises a plurality of hidden layers, each comprising a plurality of subsets of filters, each subset of filters in a given hidden layer corresponding to a specific input channel and usable for processing a target image or derivatives thereof of the specific input channel. Each subset of filters of the given hidden layer comprises a target filter to be applied to the target image or derivatives thereof, and reference filters to be applied to the reference images or derivatives thereof of the target image.
(x). The optimizing of the NN requires that the reference filters always have the same value.
(xi). The optimizing of the NN requires that the target filter across the plurality of subsets of filters in the given hidden layer has the same value.
(xii). The changes to the input order include at least one of: switching an order of the reference images, and switching an order of the target image and a reference image.
(xiii). The processing circuitry is further configured to provide a background defect map indicating probability of absence of defect presence in all of the plurality of dies. The loss function can be configured to enforce, based on the background defect map and the plurality of defect maps, a likelihood of a defect appearing at same location across the plurality of dies to be minimized.
(xiv). The NN is a Convolutional Neural Network (CNN).

In accordance with other aspects of the presently disclosed subject matter, there is provided a computerized method of training a neural network (NN) usable for defect detection in a semiconductor specimen, the method comprising: obtaining a plurality of training images acquired for a plurality of dies of a training specimen, each training image associated with a ground truth defect map indicative of defect candidate distribution in the training image; feeding the plurality of training images to a plurality of input channels of the NN in an input order; processing the plurality of training images by the NN simultaneously, to obtain, for each given training image, a predicted defect map indicating probabilities of defect candidate presence in the given training image; optimizing the NN using a loss function based on the predicted defect map and the ground truth defect map associated with the given training image; and repeating the feeding, processing, and optimizing until a criterion is met, thereby obtaining a trained NN usable to provide, for a plurality of runtime images, a plurality of defect maps invariant to changes to the input order of the plurality of runtime images to the trained NN.

These aspects of the disclosed subject matter can comprise one or more of features (ix) to (xiv) listed above with respect to the system, mutatis mutandis, in any desired combination or permutation which is technically possible.

In accordance with other aspects of the presently disclosed subject matter, there is provided a non-transitory computer readable medium comprising instructions that, when executed by a computer, cause the computer to perform method steps of any of the above methods.

In accordance with other aspects of the presently disclosed subject matter, there is provided a non-transitory computer readable medium tangibly embodying data representative of a neural network (NN) usable for defect detection in a semiconductor specimen, wherein the NN comprises: an input layer having a plurality of input channels to respectively receive a plurality of runtime images in an input order; a plurality of hidden layers each comprising a plurality of subsets of filters, each subset of filters in a given hidden layer corresponding to a specific input channel and usable for processing a specific runtime image or derivatives thereof received in the specific input channel as a target image, wherein each subset of filters of the given hidden layer comprises a target filter to be applied to the target image or derivatives thereof, and reference filters to be applied to the reference images or derivatives thereof of the target image, the reference filters having the same values; and an output layer to provide, for each runtime image of the plurality of runtime images, a defect map that remains invariant, irrespective of changes to the input order. In some cases, the target filter across the plurality of subsets of filters in the given hidden layer has the same value.

### BRIEF DESCRIPTION OF THE DRAWINGS

In order to understand the disclosure and to see how it may be carried out in practice, embodiments will now be described, by way of non-limiting example only, with reference to the accompanying drawings, in which:

FIG. 1 illustrates a generalized block diagram of an examination system in accordance with certain embodiments of the presently disclosed subject matter.

FIG. 2 illustrates a generalized flowchart of automatic defect detection in runtime using a NN in accordance with certain embodiments of the presently disclosed subject matter.

FIG. 3 illustrates a generalized flowchart of training a neural network (NN) usable for defect detection in accordance with certain embodiments of the presently disclosed subject matter.

FIG. 4 shows a schematic illustration of three dies on a wafer and their corresponding images in accordance with certain embodiments of the presently disclosed subject matter.

FIG. 5 schematically illustrates an example of different input orders of input images to a NN resulting in different prediction outputs in accordance with certain embodiments of the presently disclosed subject matter.

FIG. 6 shows a simplified example illustrating how the NN is designed using linear equations at each node of the NN in accordance with certain embodiments of the presently disclosed subject matter.

FIG. 7 illustrates an example of a NN designed to avoid discrepancies in the output values due to changes in the input order in accordance with certain embodiments of the presently disclosed subject matter.

FIG. 8 shows an example of a design of a Convolutional Neural Network (CNN) in accordance with certain embodiments of the presently disclosed subject matter.

FIG. 9 shows another example of design of a CNN, where multiple sets of filters are used to extract multiple features from the input images, in accordance with certain embodiments of the presently disclosed subject matter.

FIG. 10 illustrates an example of the n^{th} and (n+1)^{th} hidden layers of the CNN in accordance with certain embodiments of the presently disclosed subject matter.

FIG. 11 shows an example of design of the last hidden layer (the layer before the output layer) and the output layer of the CNN in accordance with certain embodiments of the presently disclosed subject matter.

FIG. 12 illustrates an example of applying a softmax function to the output feature maps to obtain defect maps in accordance with certain embodiments of the presently disclosed subject matter.

### DETAILED DESCRIPTION OF EMBODIMENTS

The process of semiconductor manufacturing often requires multiple sequential processing steps and/or layers, some of which could possibly cause errors that may lead to yield loss. Examples of various processing steps can include lithography, etching, depositing, planarization, growth (such as, e.g., epitaxial growth), and implantation, etc. Various examination operations, such as defect-related examination (e.g., defect detection, defect review, and defect classification, etc.), and/or metrology-related examination (e.g., critical dimension (CD) measurements, etc.), can be performed at different processing steps/layers during the manufacturing process to monitor and control the process. The examination operations can be performed a multiplicity of times, for example after certain processing steps, and/or after the manufacturing of certain layers, or the like.

Defect-related examination can generally employ a two-phase procedure, e.g., inspection of a specimen, followed by review of sampled locations of potential defects. During the first phase, the surface of a specimen is inspected by an inspection tool at relatively higher speed and lower resolution. Defect detection is typically performed by applying a defect detection algorithm to the inspection output. Various detection algorithms can be used for detecting defects on specimens, such as Die-to-Die (D2D), Die-to-History (D2H), Die-to-Database (D2DB), Cell-to-Cell (C2C), etc.

By way of example, a classic die-to-reference detection algorithm, such as, e.g., Die-to-Die (D2D), is typically used in some cases. In D2D, an inspection image of a target die is captured, and one or more reference images are captured from one or more reference dies of the target die. In some cases, multiple reference dies are used to check whether an anomaly exists in a target die. For instance, each die on the wafer is compared with its adjacent neighboring dies, e.g., the preceding die and the subsequent die. The inspection image and the reference images are aligned and compared to each other. Difference images (and/or derivatives thereof, such as grade images) can be generated based on the difference between pixel values of the inspection image, and pixel values derived from the reference images. A detection threshold can then be applied to the difference maps, and a defect map is produced to show suspected locations on the target die having a high probability of being a true defect (also referred to as a defect of interest (DOI)).

During the second phase, at least some of the suspected locations on the defect map are more thoroughly analyzed by a review tool with relatively higher resolution, for ascertaining whether a defect candidate is indeed a DOI, and/or determining different parameters of the DOIs, such as classes, thickness, roughness, size, and so on.

In some cases, during the first phase, machine-learning based inspection can be used for defect detection. For instance, in cases where a target die is compared with its two adjacent dies, a neural network (NN) can be used to process the three input images (i.e., the inspection image of the target die and the two reference images of the two reference dies) together, and provide respective defect maps corresponding to the three dies. It is to be noted that the defect map referred to herein can be a probability score map, which comprises pixelwise scores representing the probabilities of a defect being present in respective pixels of the corresponding input image. In some cases, the defect map can also refer to a binary map where a value of 1 indicates presence of a defect at a corresponding pixel, while a value of 0 indicates no defect presence.

FIG. 4 shows a schematic illustration of three dies on a wafer and corresponding images acquired therefrom in accordance with certain embodiments of the presently disclosed subject matter.

As shown, the three dies Die_1, Die_2, and Die_3 are neighboring dies on a wafer, one adjacent to another. A given portion of the three dies is captured by an inspection tool and the three inspection images of the given portion from the three dies are acquired. As shown in the present example, a defect 402 is present at a specific location in Die_1. In some cases, the three images can be processed by a NN together for simultaneous defect detection on the three dies. In such cases, each given die can be regarded as a target die, while the other two dies are regarded as its reference dies.

For instance, when Die_1 is regarded as the target die, Die_2 and Die_3 are regarded as the reference dies of Die_1.

One problem of such NN-based detection is that sometimes the network outputs may become dependent on the input order of the three images. Specifically, the NN can be regarded as comprising an input layer having multiple input channels to respectively receive the multiple images. When the three images are fed to the input layer in a different order, the prediction output of the NN (e.g., the defect maps) might be different.

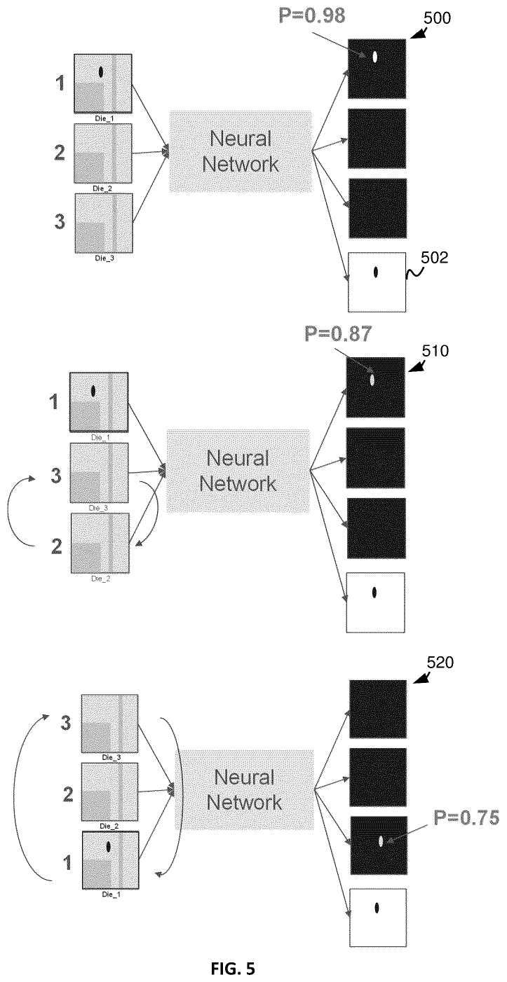

FIG. 5 schematically illustrates an example of different input orders of input images to a NN resulting in different prediction outputs in accordance with certain embodiments of the presently disclosed subject matter.

In 500, the three images are fed to the NN in an input order of Die_1, Die_2, and Die_3. Three corresponding defect maps comprising pixelwise scores representing probabilities of defect presence in the three dies are predicted together by the NN as outputs. In addition, a background defect map 502 is also provided, representing pixel-wise probabilities of no defect presence (i.e., defect absence) in any of the three dies (i.e., each value in the background defect map represents the probability that there is no defect at a corresponding pixel in all three dies). The sum of the four defect maps at any given pixel is supposed to be 1. As shown, the predicted probability of defect presence at the specific location in Die_1 is 0.98.

In 510, the three images are fed to the NN in a different input order of Die_1, Die_3, and Die_2 (i.e., Die_2 and Die_3 are switched). Similarly, three corresponding defect maps and a background defect map are provided by the NN. As shown, the predicted probability of defect presence at the specific location in Die_1 now changes to 0.87.

In the present example, when Die_1 is the target die, Die_2 and Die_3 are regarded as reference dies for Die_1. 510 thus illustrates a scenario where the input order is changed in terms of switching the order of the two reference dies, which results in a different prediction outcome for Die_1.

In comparison, in 520, the three images are fed to the NN in yet another different input order of Die_3, Die_2, and Die_1 (i.e., Die_1 and Die_3 are switched, as compared to the input order in 500). As shown, the predicted probability of defect presence at the specific location in Die_1 now changes to 0.75. Thus 520 illustrates a scenario where the input order is changed in terms of switching the order of the target die and a reference die, which results in a different prediction outcome for the target die Die_1.

Such dependency of output prediction on input order is not desirable due to various factors, such as, e.g., stability of defect detection, and difficulty of further algorithmic analysis and/or debugging. By way of example, the defects that are detected in the defect maps may be subjected to further review in order to identify any false alarms and/or missed defects of interest (DOIs). The identified false alarms and/or missed DOIs are then re-examined for the purpose of algorithmic analysis of the detection algorithm, including the NN and the model parameters thereof. The variations in the output predictions can possibly mislead such analysis, as it would be uncertain whether the variations are caused by the input order, or by the detection algorithm itself.

By way of another example, it is desired that the direction of scanning a wafer should not affect the detection result. For instance, in the example of FIG. 4, the detection result of Die_1, Die_2, and Die_3 is expected to remain the same, irrespective of the specific direction of the scan (e.g., irrespective of whether the swath containing the three dies is scanned from top to bottom (in which cases Die_1 would be the first in the input order) or from bottom to top (in which cases Die_1 would be the last in the input order)). Since the input order is necessarily affected by the changes of scanning direction, it is desired that the output prediction by the NN should be stable and remain invariant with respect to such changes.

Certain efforts have been invested in an attempt to address the above issues of output prediction variations, including, e.g., shuffling the inputs at the time of training, or creating a channel-order invariance loss to penalize output differences for different permutations of the input orders during training. However, these attempts were proven to be less effective.

Accordingly, certain embodiments of the presently disclosed subject matter propose a unique NN architecture that is specifically designed for addressing the above issues. The proposed NN is designed to be “symmetric” with respect to all the input channels, forcing the network to produce equivalent/invariant output predictions in cases where the input orders are changed, as will be detailed below.

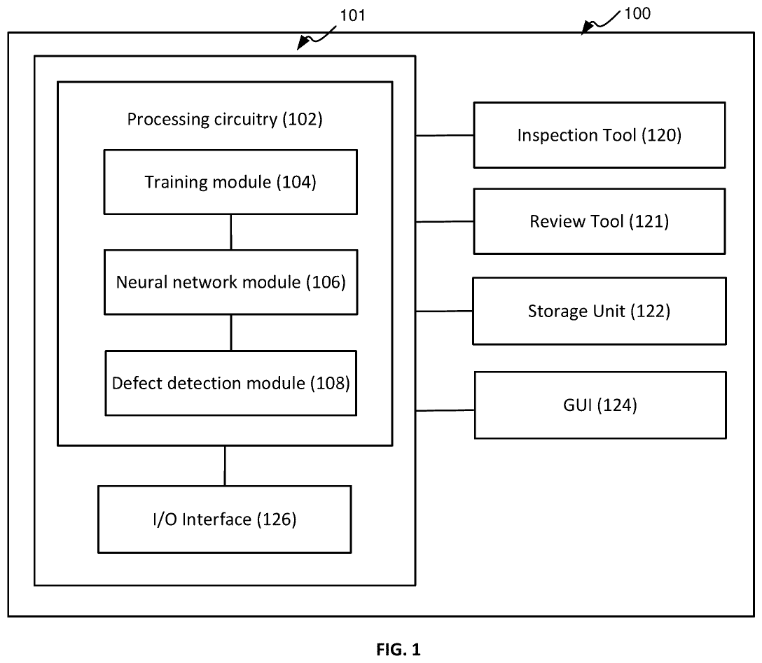

Bearing this in mind, attention is drawn to FIG. 1 illustrating a functional block diagram of an examination system in accordance with certain embodiments of the presently disclosed subject matter.

The examination system 100 illustrated in FIG. 1 can be used for examination of a semiconductor specimen (e.g., a wafer, a die, or parts thereof) as part of the specimen fabrication process. As described above, the examination referred to herein can be construed to cover any kind of operations related to defect inspection/detection, defect review, defect classification, nuisance filtration, segmentation, and/or metrology operations, etc., with respect to the specimen. System 100 comprises one or more examination tools configured to scan a specimen and capture images thereof to be further processed for various examination applications.

The term “examination tool(s)” used herein should be expansively construed

to cover any tools that can be used in examination-related processes, including, by way of non-limiting example, scanning (in a single or in multiple scans), imaging, sampling, reviewing, measuring, classifying, and/or other processes provided with regard to the specimen or parts thereof. Without limiting the scope of the disclosure in any way, it should also be noted that the examination tools can be implemented as inspection machines of various types, such as optical inspection machines, electron beam inspection machines (e.g., a Scanning Electron Microscope (SEM), an Atomic Force Microscopy (AFM), or a Transmission Electron Microscope (TEM), etc.), and so on.

The one or more examination tools can include one or more inspection tools

120 and one or more review tools 121. In some cases, an inspection tool 120 can be configured to scan a specimen (e.g., an entire wafer, an entire die, or portions thereof) to capture inspection images (typically, at a relatively high-speed and/or low-resolution) for detection of potential defects (i.e., defect candidates). During inspection, the wafer can move at a step size relative to the detector of the inspection tool (or the wafer and the tool can move in opposite directions relative to each other) during the exposure, and the wafer can be scanned step-by-step along swaths of the wafer by the inspection tool, where the inspection tool images a part/portion (within a swath) of the specimen at a time. By way of example, the inspection tool can be an optical inspection tool. At each step, light can be detected from a rectangular portion of the wafer and such detected light is converted into multiple intensity values at multiple points in the portion, thereby forming an image corresponding to the part/portion of the wafer. For instance, in optical inspection, an array of parallel laser beams can scan the surface of a wafer along the swaths. The swaths are laid down in parallel rows/columns contiguous to one another, to build up, swath-at-a-time, an image of the surface of the wafer. For instance, the tool can scan a wafer along a swath from up to down, then switch to the next swath and scan it from down to up, and so on and so forth, until the entire wafer is scanned and inspection images of the wafer are collected.

In some cases, a review tool 121 can be configured to capture review images of at least some of the defect candidates detected by inspection tools for ascertaining whether a defect candidate is indeed a defect of interest (DOI). Such a review tool is usually configured to inspect fragments of a specimen, one at a time (typically, at a relatively low-speed and/or high-resolution). By way of example, the review tool can be an electron beam tool, such as, e.g., a scanning electron microscope (SEM), etc. An SEM is a type of electron microscope that produces images of a specimen by scanning the specimen with a focused beam of electrons. The electrons interact with atoms in the specimen, producing various signals that contain information on the surface topography and/or composition of the specimen. An SEM is capable of accurately inspecting and measuring features during the manufacture of semiconductor wafers.

The inspection tool 120 and review tool 121 can be different tools located at the same or at different locations, or a single tool operated in two different modes. In some cases, the same examination tool can provide low-resolution image data and high-resolution image data. The resulting image data (low-resolution image data and/or high-resolution image data) can be transmitted—directly or via one or more intermediate systems—to system 101. The present disclosure is not limited to any specific type of examination tools and/or the resolution of image data resulting from the examination tools. In some cases, at least one of the examination tools has metrology capabilities and can be configured to capture images and perform metrology operations on the captured images. Such an examination tool is also referred to as a metrology tool.

According to certain embodiments of the presently disclosed subject matter, the examination system 100 comprises a computer-based system 101 operatively connected to the inspection tool 120 and the review tool 121, and capable of automatic defect detection based on inspection images acquired by the inspection tool 120. System 101 is also referred to as a defect detection system.

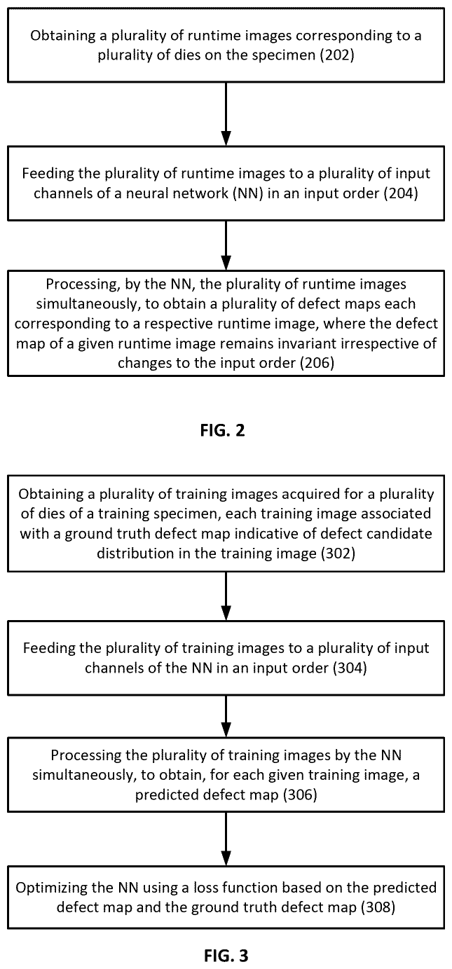

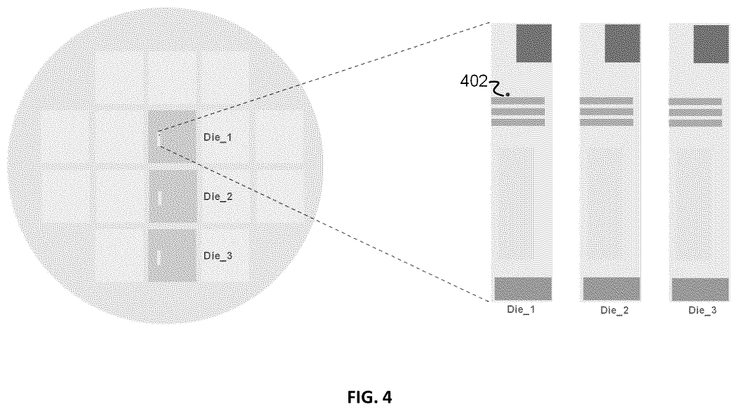

System 101 includes a processing circuitry 102 operatively connected to a hardware-based I/O interface 126 and configured to provide processing necessary for operating the system, as further detailed with reference to FIGS. 2-3. The processing circuitry 102 can comprise one or more processors (not shown separately) and one or more memories (not shown separately). The one or more processors of the processing circuitry 102 can be configured to, either separately or in any appropriate combination, execute several functional modules in accordance with computer-readable instructions implemented on a non-transitory computer-readable memory comprised in the processing circuitry. Such functional modules are referred to hereinafter as comprised in the processing circuitry.

According to certain embodiments, one or more functional modules comprised in the processing circuitry 102 of system 101 can include a neural network (NN) module 106 that was previously trained during a training/setup phase, and an optional defect detection module 108 operatively connected to the NN module 106.

Specifically, the processing circuitry 102 can be configured to obtain, via an I/O interface 126, a plurality of runtime images acquired (e.g., by an inspection tool 120) for a plurality of dies on a specimen, and feed the plurality of runtime images to a plurality of input channels of a neural network (e.g., comprised in the NN module 106) in an input order.

The NN can be configured to process the plurality of runtime images simultaneously, to obtain a plurality of defect maps, each corresponding to a respective runtime image and indicating probabilities of defect candidate presence thereof.

Specifically, each runtime image can be processed as a target image of a corresponding input channel that receives the runtime image, where the remaining images in the plurality of runtime images are used as reference images of the target image. The defect map of the target image, as outputted by the NN, can be obtained, which remains invariant irrespective of changes to the input order (of the plurality of runtime images). In other words, the defect map remains independent with respect to the input order of the plurality of runtime images.

Optionally, the defect detection module 108 can be configured to perform further review and/or analysis based on the plurality of defect maps.

In some cases, the NN module 106 and the defect detection module 108 can be regarded as part of a defect examination recipe usable for performing runtime defect examination operations, in particular defect inspection and detection operations, on acquired runtime images of a specimen.

In some embodiments, system 101 can be configured as a training system capable of training the NN during a training/setup phase using a specific training set. In such cases, one or more functional modules comprised in the processing circuitry 102 of system 101 can include a training module 104 and a NN module 106 to be trained. Specifically, the training module 104 can be configured to obtain a training set, and use the training set to train the NN module, as will be detailed below with reference to FIG. 3. As described above, the NN module 106, upon being trained, is usable to simultaneously process multiple runtime images and obtain corresponding defect maps indicating probabilities of defect candidate presence thereof.

According to certain embodiments, the NN module 106 can be implemented as various types of neural networks. The learning algorithms used by the NN module can be any of the following: supervised learning, unsupervised learning, self-supervised, semi-supervised learning, or a combination thereof, etc. The presently disclosed subject matter is not limited to the specific types of the NN module or the specific types of learning algorithms used by the NN module.

By way of example, in some cases, the NN can be implemented as a deep neural network (DNN). DNN can comprise multiple layers organized in accordance with respective DNN architecture. By way of non-limiting example, the layers of DNN can be organized in accordance with architecture of a Convolutional Neural Network (CNN), Recurrent Neural Network, Recursive Neural Networks, autoencoder,

Generative Adversarial Network (GAN), or otherwise. Optionally, at least some of the layers can be organized into a plurality of DNN sub-networks. Each layer of DNN can include multiple basic computational elements (CE), typically referred to in the art as dimensions, neurons, or nodes.

The weighting and/or threshold values associated with the CEs of a DNN and the connections thereof can be initially selected prior to training, and can be further iteratively adjusted or modified during training to achieve an optimal set of weighting and/or threshold values in a trained DNN. After each iteration, a difference can be determined between the actual output produced by DNN module and the target output associated with the respective training set of data. The difference can be referred to as an error value. Training can be determined to be complete when a loss/cost function, indicative of the error value, is less than a predetermined value, or when a limited change in performance between iterations is achieved. A set of input data used to adjust the weights/thresholds of a DNN is referred to as a training set.

It is noted that the teachings of the presently disclosed subject matter are not bound by specific architecture of the NNs as described above.

It is to be noted that while certain embodiments of the present disclosure refer to the processing circuitry 102 being configured to perform the above recited operations, the functionalities/operations of the aforementioned functional modules can be performed by the one or more processors in processing circuitry 102 in various ways. By way of example, the operations of each functional module can be performed by a specific processor, or by a combination of processors. The operations of the various functional modules, such as NN processing, and further review and analysis, etc., can thus be performed by respective processors (or processor combinations) in the processing circuitry 102, while, optionally, these operations may be performed by the same processor. The present disclosure should not be limited to being construed as one single processor always performing all the operations.

In some cases, additionally to system 101, the examination system 100 can comprise one or more examination modules, such as, e.g., defect detection module, nuisance filtration module, Automatic Defect Review Module (ADR), Automatic Defect Classification Module (ADC), metrology operation module, and/or other examination modules which are usable for examination of a semiconductor specimen.

The one or more examination modules can be implemented as stand-alone computers, or their functionalities (or at least part thereof) can be integrated with the examination tools 120 and 121. In some cases, the output of system 101, e.g., the defect maps, the list of defect candidates thereof, and/or further review/analysis result, can be provided to the one or more examination modules (such as the ADR, ADC, etc.) for further processing.

According to certain embodiments, system 100 can comprise a storage unit 122. The storage unit 122 can be configured to store any data necessary for operating system 101, e.g., data related to input and output of system 101, as well as intermediate processing results generated by system 101. By way of example, the storage unit 122 can be configured to store images of the specimen and/or derivatives thereof produced by the examination tool 120, such as, e.g., the runtime images, and the training set, as described above. Accordingly, the different types of input data as required can be retrieved from the storage unit 122 and provided to the processing circuitry 102 for further processing. The output of the system 101, such as, e.g., the defect maps, the list of defect candidates thereof, and/or further review/analysis result, can be sent to storage unit 122 to be stored.

In some embodiments, system 100 can optionally comprise a computer-based Graphical User Interface (GUI) 124 which is configured to enable user-specified inputs related to system 101. For instance, the user can be presented with a visual representation of the specimen (for example, by a display forming part of GUI 124), including the images of the specimen, the defect maps, etc. The user may be provided, through the GUI, with options of defining certain operation parameters. The user may also view the operation results or intermediate processing results, such as, e.g., the defect maps, the list of defect candidates thereof, and/or further review/analysis result, etc., on the GUI.

In some cases, system 101 can be further configured to send, via I/O interface 126, the operation results to the examination tools 120 and 121 for further processing. In some cases, system 101 can be further configured to send the results to the storage unit 122, and/or external systems (e.g., Yield Management System (YMS) of a fabrication plant (fab)). A yield management system (YMS) in the context of semiconductor manufacturing is a data management, analysis, and tool system that collects data from the fab, especially during manufacturing ramp ups, and helps engineers find ways to improve yield. A YMS helps semiconductor manufacturers and fabs manage high volumes of production analysis with fewer engineers. These systems analyze the yield data and generate reports. A YMS can be used by Integrated Device

Manufacturers (IMD), fabs, fabless semiconductor companies, and Outsourced Semiconductor Assembly and Test (OSAT).

Those versed in the art will readily appreciate that the teachings of the presently disclosed subject matter are not bound by the system illustrated in FIG. 1. Each system component and module in FIG. 1 can be made up of any combination of software, hardware, and/or firmware, as relevant, executed on a suitable device or devices, which perform the functions as defined and explained herein. Equivalent and/or modified functionality, as described with respect to each system component and module, can be consolidated or divided in another manner. Thus, in some embodiments of the presently disclosed subject matter, the system may include fewer, more, modified and/or different components, modules, and functions than those shown in FIG. 1.

Each component in FIG. 1 may represent a plurality of the particular components, which are adapted to independently and/or cooperatively operate to process various data and electrical inputs, and for enabling operations related to a computerized examination system. In some cases, multiple instances of a component may be utilized for reasons of performance, redundancy, and/or availability. Similarly, in some cases, multiple instances of a component may be utilized for reasons of functionality or application. For example, different portions of the particular functionality may be placed in different instances of the component.

It should be noted that the examination system illustrated in FIG. 1 can be implemented in a distributed computing environment, in which one or more of the aforementioned components and functional modules shown in FIG. 1 can be distributed over several local and/or remote devices. By way of example, the examination tools 120 and 121, and the system 101 can be located at the same entity (in some cases hosted by the same device) or distributed over different entities. By way of another example, as described above, in some cases, system 101 can be configured as a training system for training the NN, while in some other cases, system 101 can be configured as a runtime defect detection system using the trained NN. The training system and the runtime detection system can be located at the same entity (in some cases hosted by the same device), or distributed over different entities, depending on specific system configurations and implementation needs.

In some examples, certain components utilize a cloud implementation, e.g., are implemented in a private or public cloud. Communication between the various components of the examination system, in cases where they are not located entirely in one location or in one physical entity, can be realized by any signaling system or communication components, modules, protocols, software languages, and drive signals, and can be wired and/or wireless, as appropriate.

It should be further noted that in some embodiments at least some of examination tools 120 and 121, storage unit 122 and/or GUI 124 can be external to the examination system 100 and operate in data communication with systems 100 and 101 via I/O interface 126. System 101 can be implemented as stand-alone computer(s) to be used in conjunction with the examination tools, and/or with the additional examination modules as described above. Alternatively, the respective functions of the system 101 can, at least partly, be integrated with one or more examination tools 120 and 121, thereby facilitating and enhancing the functionalities of the examination tools in examination-related processes.

While not necessarily so, the process of operations of systems 101 and 100 can correspond to some or all of the stages of the methods described with respect to FIGS. 2-3. Likewise, the methods described with respect to FIGS. 2-3 and their possible implementations can be implemented by systems 101 and 100. It is therefore noted that embodiments discussed in relation to the methods described with respect to FIGS. 2-3 can also be implemented, mutatis mutandis as various embodiments of the systems 101 and 100, and vice versa.

Referring to FIG. 2, there is illustrated a generalized flowchart of automatic defect detection in runtime using a NN in accordance with certain embodiments of the presently disclosed subject matter.

As described above, a semiconductor specimen is typically made of multiple layers. The examination process of a specimen can be performed a multiplicity of times during the fabrication process of the specimen, for example following the processing steps of specific layers. In some cases, a sampled set of processing steps can be selected for in-line examination, based on their known impacts on device characteristics or yield. Images of the specimen or parts thereof can be acquired at the sampled set of processing steps to be examined.

For the purpose of illustration only, certain embodiments of the following description are described with respect to images of a given processing step/layer of the sampled set of processing steps. Those skilled in the art will readily appreciate that the teachings of the presently disclosed subject matter can be performed following any layer and/or processing steps of the specimen. The present disclosure should not be limited to the number of layers comprised in the specimen and/or the specific layer(s) to be examined.

A plurality of runtime images corresponding to a plurality of dies on a semiconductor specimen can be obtained (202) during runtime examination of the specimen. The plurality of runtime images can be acquired by the inspection tool 120 as described above. For instance, the images can be optical images acquired by an optical inspection tool, or electron beam (e-beam) images acquired by an electron beam tool during in-line examination of the specimen, depending on the specific examination modality thereof. A semiconductor specimen here can refer to a semiconductor wafer or parts thereof, that is fabricated and examined in the fab during a fabrication process thereof. A runtime image corresponding to a die refers to an image capturing at least part of the die. By way of example, an image can capture a region or a structure that is of interest to be examined on a semiconductor specimen.

The plurality of runtime images can be fed (204) to a plurality of input channels of a neural network (NN) (e.g., the NN module 106) in an input order. The NN is a trained network that has been previously trained during a training/setup phase, as described below with respect to FIG. 3.

The term “input order” refers to the specific sequence in which the runtime images are fed into the input channels. The input order determines the arrangement of these runtime images as they are presented to the NN for simultaneous processing. For instance, in the example of FIG. 5, if the images are fed into the NN in the order of Die_1, Die_2, and Die_3, this specific sequence is the input order.

The neural network (NN) comprises an input layer designed to receive and process multiple runtime images of semiconductor dies simultaneously. The input layer can be regarded as the first layer of the NN and serves as the initial point of data entry for the plurality of runtime images. The input layer includes a plurality of input channels, each dedicated to receiving one of the runtime images in a predefined input order. Each input channel corresponds to a specific runtime image from a die on the semiconductor specimen. Each input channel can act as a conduit for an individual runtime image, ensuring that the images are correctly aligned and fed into the NN based on the input order.

The plurality of runtime images can be processed (206) simultaneously by the NN to obtain, as output, a plurality of defect maps each corresponding to a respective runtime image and indicating probabilities of defect candidate presence thereof. Specifically, each runtime image can be processed as a target image of a corresponding input channel that receives the runtime image, where the remaining images in the plurality of runtime images are used as reference images of the target image. A reference image corresponds to a target image in the sense that it captures a similar region containing similar patterns as those of the target image, thus can be used as a reference to be compared to the target image. The defect map of the target image, as outputted by the NN, can be obtained, which remains invariant, irrespective of changes to the input order.

As described above, the NN is specifically designed to address the problem of output prediction variations caused due to changes of the input order. Using a NN with such specific architecture enables that the defect map of any target image within the plurality of runtime images remains invariant irrespective of changes to the input order, ensuring consistent defect detection results, regardless of the sequence in which the runtime images are fed into the NN.

Changes to the input order referred to herein should be construed to cover at least one of the two scenarios as exemplified in FIG. 5 above: switching the order of reference images, and switching the order of the target image and a reference image.

In the first scenario, the target die remains the same, but the sequence of the reference dies is altered. For instance, if the NN is initially fed with images in the order of Die_1 (target), Die_2 (reference), and Die_3 (reference), switching the reference dies results in a new input order such as Die_1 (target), Die_3 (reference), and Die_2 (reference). In the second scenario, the position of the target die itself is changed relative to the reference dies. For example, if the initial input order is Die_1 (target), Die_2 (reference), and Die_3 (reference), changing the target die position results in a new input order such as Die_3 (target), Die_2 (reference), and Die_1 (reference).

According to certain embodiments, the NN as proposed in the present disclosure can comprise a plurality of hidden layers, each comprising a plurality of subsets of filters. Each subset of filters corresponds to a specific input channel and is usable for processing a target image (or derivatives thereof, in cases where the hidden layer is not the first hidden layer) of the specific input channel. The derivatives of the runtime image may refer to one or more feature maps of the specific runtime image resulting from a previous hidden layer. For instance, for the second hidden layer, a given subset of filters corresponding to a specific input channel is used to process one or more feature maps of the target image resulting from the first hidden layer.

A given subset of filters comprising a target filter to be applied to the target image (or derivatives thereof) and reference filters to be applied to the reference images (or derivatives thereof) of the target image. In some embodiments, the reference filters are designed to have the same/equivalent values. In some cases, additionally, the target filter in each subset of filters of the plurality of subsets has the same value (as of the target filter in other subsets of filters).

The above-proposed NN architecture is specifically designed to be symmetric with respect to the input channels, addressing both aspects of input order changes as described above. This symmetry ensures that the defect maps produced by the NN are invariant to changes in the input order. The symmetry encompasses two aspects as detailed below.

The first aspect is regarding the design of reference filters. Within each subset of filters, the reference filters applied to the reference images have the same values. This design ensures that the NN applies the same reference filters to the reference images, regardless of the specific order of the reference images. For example, whether the input order is Die_1, Die_2, and Die_3 or Die_1, Die_3, and Die_2, the reference filters applied to Die_2 and Die_3 will be the same.

The second aspect is regarding the design of the target filter. Each subset of filters includes a target filter that is applied to the target image in each input channel. This specific filter has the same value across all subsets of filters in each hidden layer. This design ensures that the NN applies the same specific filter to the target image, regardless of the position of the target image in the input order. For instance, if the input order changes from Die_1, Die_2, and Die_3 to Die_3, Die_2, and Die_1, the specific filter applied to Die_1 remains consistent.

By incorporating these symmetric aspects, the NN architecture guarantees that the defect detection results are stable and invariant to the changes in the input order. This design can effectively address the variations in prediction outcomes caused by different input sequences, ensuring reliable and consistent defect detection across all runtime images.

It is to be understood that the terms “the same” or “equivalent” do not necessarily imply exact numerical identity. Rather, these terms are intended to encompass filters that are sufficiently similar in their functional characteristics, to ensure consistent and symmetric processing within the neural network. Such similarity may include minor variations in the filter values that do not significantly impact the overall performance and output of the neural network. Thus, the scope of the present disclosure should include filters that achieve equivalent functionality, even if their values are not precisely identical.

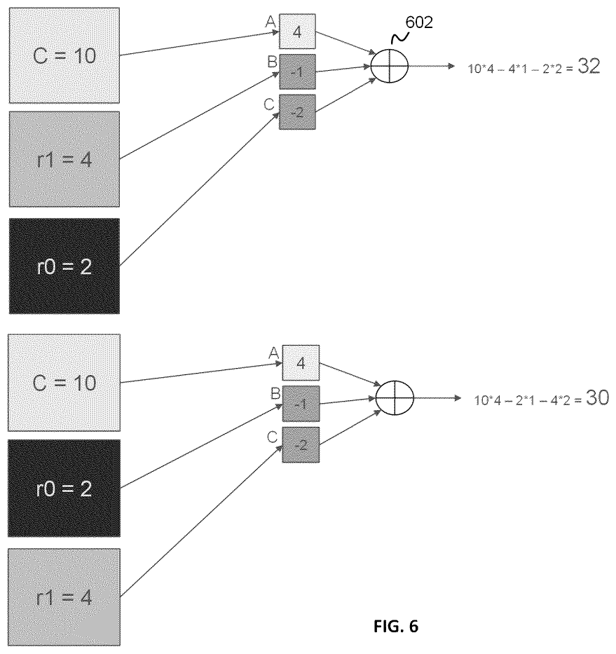

For the purpose of intuitive illustration of the proposed neural network (NN) architecture, FIG. 6 shows a simplified example illustrating how the NN is designed, using linear equations at each node of the NN in accordance with certain embodiments of the presently disclosed subject matter.

Assume that the filters (also referred to as weights) A, B, and C at a node 602 in the NN are learned through a training process to satisfy a specific inspection application. As shown in the figure, three inputs are provided to a given node of the NN, where c represents a value from the current inspection die (i.e., the target die), r1 represents a value from the first reference die, and r0 represents a value from the second reference die. In the present example, c=10, r1=4 and r0=2.

In the initial setup (shown in the upper illustration), the inputs are provided to the NN in the order of c, r1, and r0. The output value is calculated using a linear equation with the corresponding weights A, B, and C applied to these inputs. The linear equation at the node can be expressed as: Output=A×c+B×r1+C×r0. Assuming specific learned values for the weights are A=4, B=−1, and C=−2, the output can be computed as follows: Output=4×10-1×4-2×2=32.

When changing the input order by switching the positions of r1 and r0, the new input order is c, r0, and r1. As the inputs are switched, the linear equation at the node can be expressed as: Output=A×c+B×r0+C×r1. The output can be computed as follows: Output=4×10−1×2−2×4=30.

Similarly, although not illustrated separately, when changing the input order by switching the positions of c with any of r0 and r1, the output value changes as well.

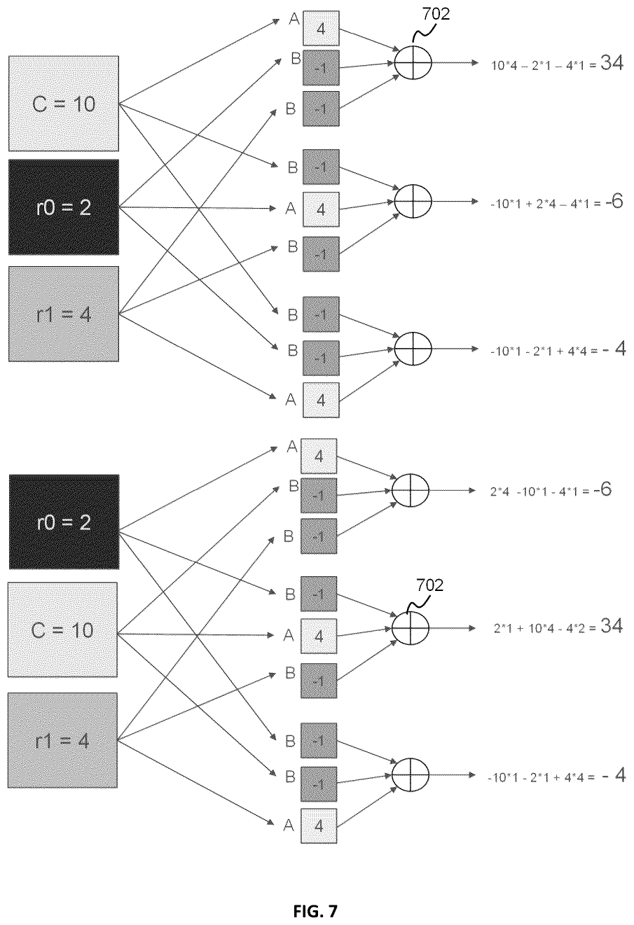

FIG. 7 illustrates an example of a NN designed to avoid discrepancies in the output values due to changes in the input order in accordance with certain embodiments of the presently disclosed subject matter.

As shown, the NN as presently proposed is designed to apply the same values to the reference filters. Specifically, the values of B and C are set to be equal (i.e., B−C=−1, thus C is replaced by B in the figure). Additionally, the target filter A is set to the same value, such as 4, in all subsets of filters (there are three subsets of filters in the example of FIG. 7).

Under such symmetric configuration, the linear equation at node 702 in the upper illustration (where the input order is c, r0 and r1) can be expressed as: Output=A×c+B×r0+B×r1. The output value at this node can be computed as follows: Output=4×10−1×2−1×4=34.

In the lower illustration, the input order is changed to r0, c and r1, i.e., the target die c and reference die r0 are switched. In such cases, the linear equation at the same node 702 can be expressed as: Output=B×10+A×c+B×r1. The output value at this node can be computed as follows: Output=−1×2+4×10−1×4=34.

In both cases, the output value corresponding the target die c is 34, demonstrating the invariance of the output to changes in input order due to the symmetric design of the NN filters. Similarly, the output values corresponding to the other two dies r0 and r1 also remain unchanged. As shown, the output value for r0 in both cases is −6, while the output value for r1 in both cases is −4, indicating that when r0 and r1 is each regarded as the target die respectively, their output value also remains invariant to the input order changes.

By ensuring the reference filters have the same values and setting a consistent value for the target filter, the proposed NN architecture achieves symmetric processing. Such design addresses the issue of output variations caused by different input orders, providing reliable and consistent defect detection results in semiconductor inspection applications.

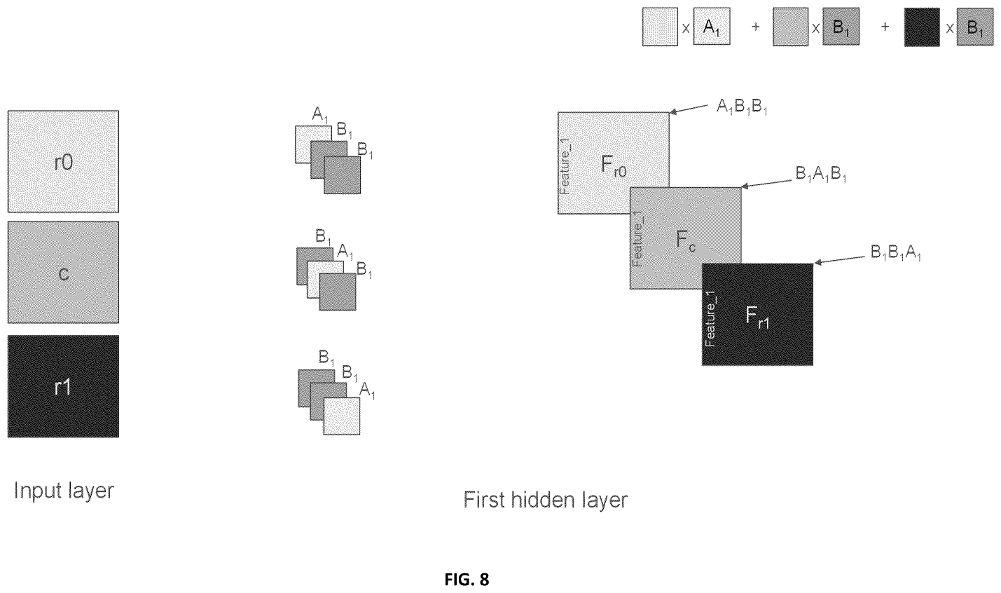

Having illustrated a simplified example above, FIG. 8 now shows an example of a design of a Convolutional Neural Network (CNN) in accordance with certain embodiments of the presently disclosed subject matter. FIG. 8 depicts an input layer receiving three inputs in a specific order, followed by the first hidden layer comprising three subsets of filters corresponding to the three input channels.

Specifically, the input layer of the CNN is a three-channel input layer, and is configured to receive three inputs in a predefined order: r0, c, and r1. These inputs represent the images captured from three different dies on a semiconductor wafer, where c is the image from the target die, and r0 and r1 are images from the reference dies. For each input channel, the input image received in the channel is regarded as the target image of that channel. By way of example, r0 is regarded as the target image in the first input channel, where c and r1 are regarded as its reference images for processing. Similarly, c is regarded as the target image in the second input channel, where r0 and r1 are regarded as its reference images for processing.

The first hidden layer of the CNN comprises three subsets of filters, each

subset corresponding to one of the input channels. The filters in each subset are convolved with the input images to extract relevant features. Specifically, the subset of filters for the first input channel of r0 includes filters A1, B1, and B1. These filters are respectively convolved with the three input images r0, c, and r1. The convolved outputs are then summed to obtain the output feature map for the first input channel of r0.

Similarly, the subset of filters for the second input channel of c includes filters B1, A1, and B1. These filters are respectively convolved with the three input images r0, c, and r1. The convolved outputs are then summed to obtain the output feature map for the second input channel of c. The subset of filters for the third input channel of r1 includes filters B1, B1 and A1. These filters are also respectively convolved with the three input images r0, c, and r1, and the output feature map is obtained for the third input channel of r1.

Each subset of filters includes a target filter (A1) that is applied to the target image, and two reference filters (B1) that are applied to the reference images. The reference filters (B1) have the same values to ensure consistent processing of the reference images, regardless of their order.

By way of example, the convolution operation is performed by sliding the filters over the input images and computing the dot product between the filters and the receptive fields of the input images. This operation produces feature maps that capture specific patterns or features in the input images.

After processing by the first hidden layer, three output feature maps are generated, corresponding to the three input images. These feature maps serve as inputs to the subsequent hidden layer (i.e., the second hidden layer) and represent the extracted features (referred to as feature_1 in the present example) in the three input images.

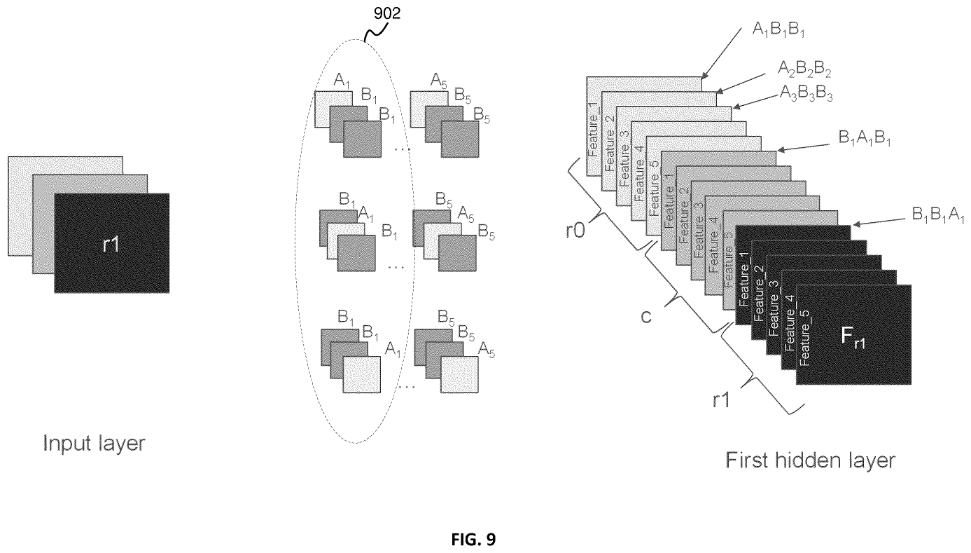

In the above example of FIG. 8, one set of filters (including three subsets of filters) is exemplified for extracting one specific feature: feature_1. FIG. 9 shows another example of design of a CNN, where multiple sets of filters are used to extract multiple features from the input images, in accordance with certain embodiments of the presently disclosed subject matter. The figure demonstrates how the CNN processes the inputs to generate multiple output feature maps for each input channel, reflecting the respective extracted features.

The input layer of the CNN is similarly configured to receive three inputs in a predefined order: r0 (reference 0), c (target), and r1 (reference 1). The first hidden layer of the CNN comprises multiple sets of filters, with each set designed to extract a specific feature. In this example, there are five sets of filters for extracting five different features: feature_1 to feature_5. Each set of filters includes three subsets corresponding to the three input channels.

Specifically, by way of example, the first set of filters 902 for extracting feature_1 includes three subsets of filters: the subset for input channel of r0, including filters A1, B1, and B1, the subset for input channel of c, including filters B1, A1, and B1, and the subset for input channel of r1, including filters B1, B1 and A1. The other sets of filters are constructed in a similar manner, thus will not be specified one by one for purpose of brevity.

After processing by the first hidden layer, multiple output feature maps are generated for each input channel. In this example, five feature maps are produced for each input image (each of r0, c, and r1), corresponding to the five sets of filters (feature_1 to feature_5). These feature maps reflect the respective extracted features in the input images. For instance, the output feature maps for r0 include five feature maps generated corresponding to feature_1 to feature_5, as illustrated. By using multiple sets of filters for extracting different features, the CNN architecture can ensure comprehensive feature extraction from the input images, thus improving detection performance.

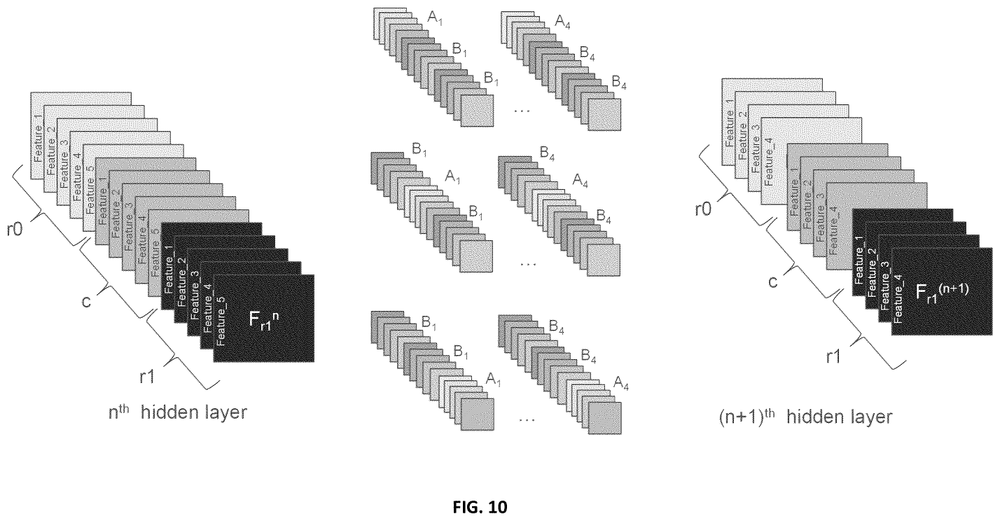

FIG. 10 illustrates an example of the n^{th} and (n+1)^{th} hidden layers of the CNN in accordance with certain embodiments of the presently disclosed subject matter. This example demonstrates how the feature maps generated by one hidden layer serve as inputs to the next hidden layer, and how the filter sets are adapted to process these inputs.

The input to the nth hidden layer (e.g., starting from the second hidden layer) includes multiple feature maps generated by the preceding hidden layer. Specifically, there are five feature maps for each input channel, resulting in a total of 15 feature maps (five feature maps for r0, five feature maps for c, and five feature maps for r1).

To process these multiple input feature maps, the number of filters in each subset of filters in the nth hidden layer is increased to match the number of input feature maps. Each subset of filters is designed to convolve with all input feature maps from the corresponding input channel.

Specifically, taking the first subset of filters for input channel of r0 for example, the original filters A1, B1, and B1 are duplicated five times to match the five input feature maps. This gives rise to a total of 15 filters. In some cases, the duplications can include varying the values of the filters rather than exact copies. For instance, the filter Al can have four duplicates with variations in filter values, resulting in A11, A12, A13, A14, and A15 (illustrated by different gray levels in the figure). Similarly, the reference filters B1 are duplicated with variations, resulting in B11, B12,B13, B14, and B15.

The convolution operation in the nth hidden layer involves applying the enlarged subsets of filters to the input feature maps. The filters are convolved with the input feature maps, and the convolved outputs are summed to produce the output feature maps for each channel. For instance, each filter is convolved across the width and height of an input feature map, producing a two-dimensional activation map which gives the responses of that filter at every spatial position. Stacking the activation maps for all filters along the depth dimension forms a full output feature map of the specific layer, representative of extracted features/attributes at this layer.

In the present example, there are four sets of filters corresponding to four features: feature_1 to feature_4, each constructed in a similar manner as the first set.

After processing by the nth hidden layer, multiple output feature maps are

generated for each input channel, similar to the output of the first hidden layer. These output feature maps serve as inputs to the (n+1)^{th} hidden layer. In this example, four output feature maps are produced for each input image, corresponding to the four sets of filters (feature_1 to feature_4).

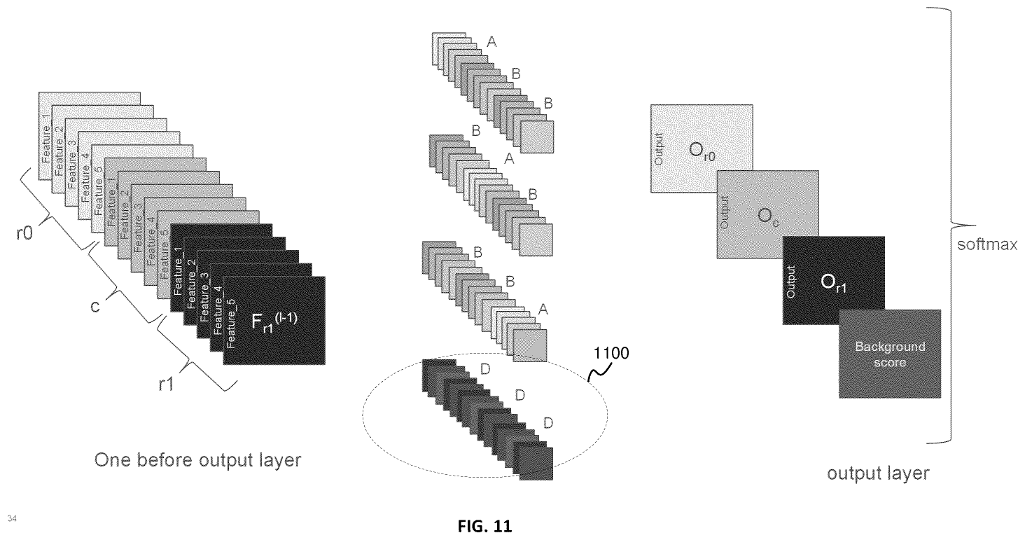

FIG. 11 shows an example of design of the last hidden layer (the layer before

the output layer) and the output layer of the CNN in accordance with certain embodiments of the presently disclosed subject matter. This example demonstrates how the feature maps generated by the last hidden layer are processed to produce the final output defect maps.

The input to the last hidden layer comprises multiple feature maps generated

by the preceding hidden layer. Specifically, there are five feature maps for each input channel, resulting in a total of 15 input feature maps.

There is one set of filters used in the example, comprising three subsets of filters. Similarly, the number of filters used in each subset of filters is also increased to match the number of input feature maps. For instance, a total of 15 filters are used in each subset of filters corresponding to the 15 input feature maps.

In some embodiments, in addition to the three subsets of filters corresponding to the input channels, one more subset of filters 1100 is added for generating the background output feature map. This subset of filters is duplicated from a subset of filters D, D, and D, to remain symmetric in structure. This symmetry ensures that the background scores in the background output feature map also does not depend on the input order. This symmetry may be sometimes essential as the background score gets combined through a function (e.g., softmax) with the output feature maps corresponding to the input channels, to produce the final scores. Any variance in the background score due to input order variance would be reflected in the final output, if not taken care of.

The output of the last hidden layer, as presented in the output layer, comprises four output feature maps: three output feature maps corresponding to the three input channels, and one output feature map corresponding to the background.

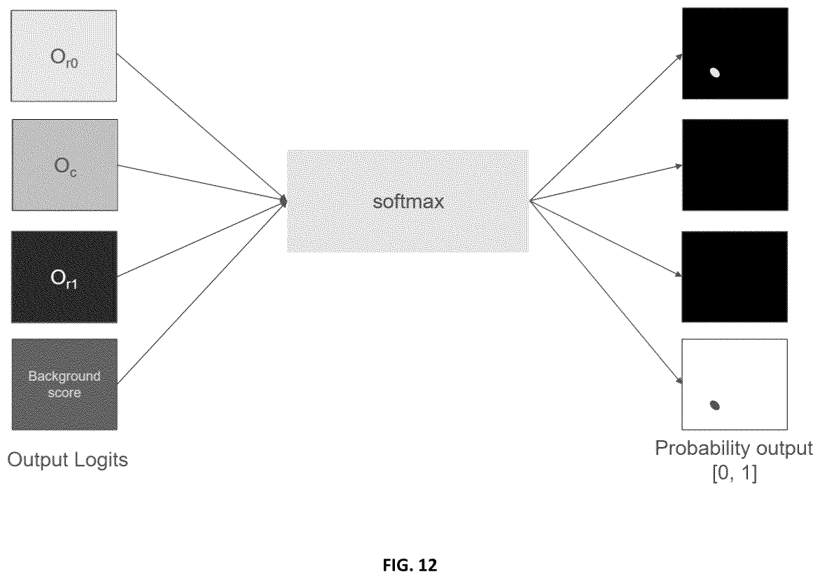

In some cases, a function, such as softmax, can be applied to all the output feature maps to obtain final output defect maps. FIG. 12 illustrates an example of applying a softmax function to the output feature maps to obtain defect maps in accordance with certain embodiments of the presently disclosed subject matter.

The softmax function is a mathematical function that normalizes the output values so that they sum to 1 across the four output maps for each pixel location. As shown, after applying the softmax function, four corresponding defect maps are generated. For the first three output maps, each pixel value indicates the probability of defect presence at a corresponding pixel location of a corresponding input image. For the fourth output map, which is also called the background probability score map, each pixel value indicates the probability of non-presence of defect in any one of the input images at that pixel location.

By using the softmax function, the NN is forced to share the defect probability over the plurality of defect maps for each given pixel location. This enforces an inductive bias that the probability of having a defect in the exact same location over a few consecutive dies is negligible.

An inductive bias is an assumption the NN model makes to generalize better from the training data. In this case, the inductive bias is that defects are unlikely to occur at the exact same pixel location across multiple consecutive dies. When the softmax function is applied, it distributes the total probability of a defect occurring at each pixel location across the four output feature maps (three for the input channels and one for the background). This means that if a pixel in one die has a high probability of being defective, the same pixel in the consecutive dies will have a lower probability.

By normalizing the probabilities across the feature maps, the softmax function ensures that the likelihood of the same defect appearing at the exact same location across multiple dies is minimized. This reflects the real-world scenario, where defects typically occur at random or specific locations, rather than consistently at the same pixel across different dies.

In some embodiments, once the plurality of defect maps corresponding to the plurality of runtime images are generated by the Convolutional Neural Network (CNN), these defect maps can be further reviewed by a review tool to verify whether each of the identified defect candidates are indeed a Defect of Interest (DOI) or a false alarm.

The defect maps generated by the NN highlight the locations of potential defects. These defect locations are considered defect candidates and are subject to further review. The review tool performs an in-depth analysis of the defect maps to validate the identified defect candidates. This may involve examining each identified defect candidate, and classifying the defect candidate as either a DOI or a false alarm.

In some cases, upon the review, one or more locations may be identified as false alarms or missed DOIs. These locations may require re-examination to ensure accurate defect detection. Specifically, the inspection tool can acquire one or more new images of the one or more locations identified as false alarms or missed DOIs. These new images provide updated visual data for re-evaluation. The newly acquired images are processed by the NN to generate new defect maps. The same neural network architecture used for the initial inspection is applied to ensure consistency in defect detection. The new defect maps are subjected to algorithmic analysis. This analysis compares the new defect maps with ground truth information provided by the review tool. Ground truth information includes verified data on the actual presence or absence of defects at these specific locations. For instance, based on the comparison, the parameters (e.g., filter values/weights) of the neural network may be adjusted to improve detection performance (e.g., in terms of capture rate and/or false alarm rate (FAR)). This adjustment ensures that the NN can better distinguish between true defects and false alarms in future inspections.

This post-processing step can improve the accuracy and reliability of the defect detection performance by the NN.

Referring now to FIG. 3, there is illustrated a generalized flowchart of training a neural network (NN) usable for defect detection in accordance with certain embodiments of the presently disclosed subject matter.

For purpose of training a NN, training data should be collected. Specifically, a plurality of training images acquired for a plurality of dies of a training specimen can be obtained (302) (e.g., by the training module 104). The training specimen shares the same design as the specimens to be examined in runtime. Each training image is associated with a ground truth defect map indicative of defect spatial distribution in the training image. The spatial distribution may refer to presence or absence of a defect in each pixel of the training image. The ground truth data provides accurate labels for the presence or absence of DOIs, which enables the NN to learn the correct mappings from images to defect probabilities under supervised learning.

The ground truth data can be obtained in various ways, such as, e.g., via manual annotation, from a review tool, etc. By way of example, a review tool can be used to capture review images with higher resolution at locations of the defect candidates from a defect map of a training specimen, and review the review images for ascertaining whether a defect candidate is a DOI or nuisance. The defect presence provided by the review tool and their locations on the defect map can be regarded as ground truth data for a training image of the specimen.

The plurality of training images can be fed (304) to a plurality of input channels of the NN in an (predefined) input order. The input order determines the sequence in which the training images are presented to the NN. This order should be maintained consistently throughout the training process to ensure systematic learning.

The NN can be initially constructed in a similar manner as described above with reference to FIG. 2. Specifically, the NN can comprise a plurality of hidden layers each comprising a plurality of subsets of filters, each subset of filters in a given hidden layer corresponding to a specific input channel and usable for processing a specific training image or derivatives thereof received in the specific input channel as a target image. Each subset of filters of the given hidden layer comprises a target filter to be applied to the target image or derivatives thereof, and reference filters to be applied to the reference images or derivatives thereof of the target image.

The plurality of training images can be simultaneously processed (306) by the NN, to obtain, for each given training image, a predicted defect map indicating probabilities of defect candidate presence in the given training image.

The NN can be optimized (308) using a loss function based on the predicted

defect map and the ground truth defect map associated with the given training image. The loss function can be configured to measure the discrepancy between the predicted defect map and the ground truth defect map. By way of example, loss functions that can be used in the present case include cross-entropy loss, mean squared error, or custom loss functions designed specifically for defect detection. The loss function guides the optimization process by adjusting the values of the filters within the NN to minimize the error between the predicted defect map and the ground truth defect map. This optimization can be typically performed using gradient descent algorithms such as stochastic gradient descent (SGD), Adam, etc.

The optimization of the NN requires that the reference filters in a given subset

of filters in a hidden layer always have the same value. Additionally, the optimization requires that the target filter across the plurality of subsets of filters in a given hidden layer has the same value. By maintaining these constraints, the NN keeps the symmetric architecture described above, ensuring that the defect maps remain invariant, irrespective of changes to the input order.

In some cases, the process of feeding, processing, and optimizing, as described above, can be repeated iteratively until a criterion is met. The training process may typically involve multiple iterations, also known as epochs, where the entire set of training images is repeatedly fed into the NN. During each iteration, the NN's parameters are adjusted to improve its accuracy and performance. The iterative training process can be continued until a predefined criterion is met. The criterion can be based on various factors, such as, e.g., reaching a certain level of accuracy, achieving a low loss value, or completing a specified number of epochs.

In some embodiments, the training process can further comprise providing a background defect map, as part of the output of the NN, indicating probability of absence of defect presence in all of the plurality of dies. In such cases, the loss function can be configured to enforce, based on the background defect map and the plurality of defect maps (e.g., by combining these defect maps), a likelihood of a defect appearing at same location across the plurality of dies to be minimized.

Upon training, a trained NN is obtained. The trained NN can be deployed in real-time inspection scenarios to analyze runtime images and generate defect maps.

These defect maps are invariant to changes in the input order, ensuring consistent and reliable defect detection performance.

According to certain embodiments, the present disclosure discloses a unique NN usable for defect detection in a semiconductor specimen. The NN comprises: an input layer having a plurality of input channels to respectively receive a plurality of runtime images in an input order; a plurality of hidden layers each comprising a plurality of subsets of filters, each subset of filters in a given hidden layer corresponding to a specific input channel and usable for processing a specific runtime image or derivatives thereof received in the specific input channel as a target image, each subset of filters of the given hidden layer comprising a target filter to be applied to the target image or derivatives thereof, and reference filters to be applied to the reference images or derivatives thereof of the target image, the reference filters having the same values; and an output layer to provide, for each runtime image of the plurality of runtime images, a defect map that remains invariant, irrespective of changes to the input order. In some cases, the target filter across the plurality of subsets of filters in the given hidden layer has the same value.

The present disclosure also discloses a non-transitory computer readable storage medium tangibly embodying data representative of the NN as proposed above.

It is to be noted that examples illustrated in the present disclosure, such as, e.g., the exemplified dies and images, the exemplified NN structure and filters, the loss functions, the training datasets, etc., are illustrated for exemplary purposes, and should not be regarded as limiting the present disclosure in any way. Other appropriate examples/implementations can be used in addition to, or in lieu of the above.

Among advantages of certain embodiments of the presently disclosed subject matter as described herein, is providing a NN-based defect detection system capable of inspecting multiple runtime images and generating defect maps that are invariant to changes in the input order of the runtime images, thus enabling reliable and consistent defect detection, and eliminating discrepancies caused by different sequences of input images.

The above technical effects are enabled by the symmetric design of the NN architecture, which includes the use of reference filters with the same values (addressing the order change of switching between reference images) and target filters with consistent values across the subsets (addressing the order change of switching between target reference images). Such symmetric design ensures that the defect maps remain stable and invariant. This symmetric processing is maintained through the training and optimization processes, where the filters are adjusted to preserve this architecture.

Among further advantages of certain embodiments of the presently disclosed subject matter as described herein, is providing accurate defect detection by leveraging a symmetric NN specifically designed as described above. This architecture enables the precise identification of defect candidates, enhancing the overall detection performance.

Among further advantages of certain embodiments of the presently disclosed subject matter as described herein, is the possibility of reducing the occurrence of false alarms and missed DOIs, and providing a more reliable defect detection outcome. This reduction is achieved through the re-examination process and the use of a review tool to validate defect candidates.

The process of acquiring new images for re-examination, processing these images through the NN, and performing algorithmic analysis with ground truth data, ensures that false alarms and missed defects are accurately identified and corrected, and assist in debugging the detection algorithm, including tuning the NN and the parameters thereof.

Among further advantages of certain embodiments of the presently disclosed subject matter as described herein, is providing an efficient training process that optimizes the NN to perform accurate and consistent defect detection. The training process ensures that the NN learns to produce reliable defect maps based on ground truth data.

The training process involves obtaining a plurality of training images with

associated ground truth defect maps, feeding these images to the NN, processing them to generate predicted defect maps, and optimizing the NN using a loss function. The iterative nature of the training process, combined with the use of symmetric filters, ensures that the NN is effectively trained to detect defects accurately and consistently. It is to be understood that the present disclosure is not limited in its application

to the details set forth in the description contained herein or illustrated in the drawings.

In the present detailed description, numerous specific details are set forth in order to provide a thorough understanding of the disclosure. However, it will be understood by those skilled in the art that the presently disclosed subject matter may be practiced without these specific details. In other instances, well-known methods, procedures, components, and circuits have not been described in detail so as not to obscure the presently disclosed subject matter.

Unless specifically stated otherwise, as apparent from the present discussions, it is appreciated that throughout the specification discussions utilizing terms such as “obtaining”, “examining”, “feeding”, “processing”, “using”, “providing”, “applying”, “re-examining”, “acquiring”, “performing”, “reviewing”, “training”, “optimizing”, “repeating”, or the like, refer to the action(s) and/or process(es) of a computer that manipulate and/or transform data into other data, said data represented as physical, such as electronic, quantities and/or said data representing the physical objects.

The terms “computer”, “computer-based system” or “computerized system”

should be expansively construed to cover any kind of hardware-based electronic device with a data processing circuitry (e.g., digital signal processor (DSP), a graphics processing unit (GPU), a field programmable gate array (FPGA), including, by way of non-limiting example, the examination system, the defect detection system, and respective parts thereof disclosed in the present application. The data processing circuitry (designated also as processing circuitry) can comprise, for example, one or more processors operatively connected to computer memory, loaded with executable instructions for executing operations, as further described below. The data processing circuitry encompasses a single processor or multiple processors, which may be located in the same geographical zone, or may, at least partially, be located in different zones, and may be able to communicate together.

The one or more processors referred to herein can represent one or more general-purpose processing devices such as a microprocessor, a central processing unit, or the like. More particularly, a given processor may be one of a complex instruction set computing (CISC) microprocessor, a reduced instruction set computing (RISC) microprocessor, a very long instruction word (VLIW) microprocessor, a processor implementing other instruction sets, or a processor implementing a combination of instruction sets. The one or more processors may also be one or more special-purpose processing devices such as an application specific integrated circuit (ASIC), a field programmable gate array (FPGA), a digital signal processor (DSP), a network processor, or the like. The one or more processors are configured to execute instructions for performing the operations and steps discussed herein.

The memories referred to herein can comprise one or more of the following: internal memory, such as, e.g., processor registers and cache, etc., main memory such as, e.g., read-only memory (ROM), flash memory, dynamic random access memory (DRAM) such as synchronous DRAM (SDRAM) or Rambus DRAM (RDRAM), etc.

The terms “non-transitory memory” and “non-transitory storage medium” used herein should be expansively construed to cover any volatile or non-volatile computer memory suitable to the presently disclosed subject matter. The terms should be taken to include a single medium or multiple media (e.g., a centralized or distributed database, and/or associated caches and servers) that store the one or more sets of data and/or instructions. The terms shall also be taken to include any medium that is capable of storing or encoding a set of instructions for execution by the computer and that cause the computer to perform any one or more of the methodologies of the present disclosure. The terms shall accordingly be taken to include, but not be limited to, a read only memory (“ROM”), random access memory (“RAM”), magnetic disk storage media, optical storage media, flash memory devices, etc.

The term “specimen” used in this specification should be expansively construed to cover any kind of physical objects or substrates including wafers, masks, reticles, and other structures, combinations and/or parts thereof used for manufacturing semiconductor integrated circuits, magnetic heads, flat panel displays, and other semiconductor-fabricated articles. A specimen is also referred to herein as a semiconductor specimen, and can be produced by manufacturing equipment executing corresponding manufacturing processes.

The term “examination” used in this specification should be expansively construed to cover any kind of operations related to defect detection, defect review, and/or defect classification of various types, segmentation, and/or metrology operations during and/or after the specimen fabrication process. Examination is provided by using non-destructive examination tools during or after manufacture of the specimen to be examined. By way of non-limiting example, the examination process can include runtime scanning (in a single or in multiple scans), imaging, sampling, detecting, reviewing, measuring, classifying, and/or other operations provided with regard to the specimen or parts thereof, using the same or different inspection tools. Likewise, examination can be provided prior to manufacture of the specimen to be examined, and can include, for example, generating an examination recipe(s) and/or other setup operations. It is noted that, unless specifically stated otherwise, the term “examination”, or its derivatives used in this specification, is not limited with respect to resolution or size of an inspection area. A variety of non-destructive examination tools includes, by way of non-limiting example, scanning electron microscopes (SEM), atomic force microscopes (AFM), optical inspection tools, etc.

The term “metrology operation” used in this specification should be expansively construed to cover any metrology operation procedure used to extract metrology information relating to one or more structural elements on a semiconductor specimen. In some embodiments, the metrology operations can include measurement operations, such as, e.g., critical dimension (CD) measurements performed with respect to certain structural elements on the specimen, including but not limiting to the following: dimensions (e.g., line widths, line spacing, contact diameters, size of the element, edge roughness, gray level statistics, etc.), shapes of elements, distances within or between elements, related angles, overlay information associated with elements corresponding to different design levels, etc. Measurement results such as measured images are analyzed, for example, by employing image-processing techniques. Note that, unless specifically stated otherwise, the term “metrology”, or derivatives thereof used in this specification, is not limited with respect to measurement technology, measurement resolution, or size of inspection area.

The term “defect” used in this specification should be expansively construed to cover any kind of abnormality or undesirable feature/functionality formed on a specimen. In some cases, a defect may be a defect of interest (DOI) which is a real defect that has certain effects on the functionality of the fabricated device, thus is in the customer's interest to be detected. For instance, any “killer” defects that may cause yield loss can be indicated as a DOI. In some other cases, a defect may be a nuisance (also referred to as “false alarm” defect) which can be disregarded because it has no effect on the functionality of the completed device and does not impact yield.

The term “defect candidate” used in this specification should be expansively construed to cover a suspected defect location on the specimen which is detected to have relatively high probability of being a defect of interest (DOI). Therefore, a DOI candidate, upon being reviewed/tested, may actually be a DOI, or, in some other cases, it may be nuisances, or random noise that can be caused by different variations (e.g., process variation, color variation, mechanical and electrical variations, etc.) during inspection.

The term “design data” used in the specification should be expansively construed to cover any data indicative of hierarchical physical design (layout) of a specimen. Design data can be provided by a respective designer and/or can be derived from the physical design (e.g., through complex simulation, simple geometric and Boolean operations, etc.). Design data can be provided in different formats as, by way of non-limiting examples, GDSII format, OASIS format, etc. Design data can be presented in vector format, grayscale intensity image format, or otherwise.

The term “image(s)” or “image data” used in the specification should be expansively construed to cover any original images/frames of the specimen captured by an examination tool during the fabrication process, derivatives of the captured images/frames obtained by various pre-processing stages, and/or computer-generated synthetic images (in some cases based on design data). Depending on the specific way of scanning (e.g., one-dimensional scan such as line scanning, two-dimensional scan in both x and y directions, or dot scanning at specific spots, etc.), image data can be represented in different formats, such as, e.g., as a gray level profile, a two-dimensional image, or discrete pixels, etc. It is to be noted that in some cases the image data referred to herein can include, in addition to images (e.g., captured images, processed images, etc.), numeric data associated with the images (e.g., metadata, hand-crafted attributes, etc.). It is further noted that images or image data can include data related to a processing step/layer of interest, or a plurality of processing steps/layers of a specimen.

It is appreciated that, unless specifically stated otherwise, certain features of the presently disclosed subject matter, which are described in the context of separate embodiments, can also be provided in combination in a single embodiment. Conversely, various features of the presently disclosed subject matter, which are described in the context of a single embodiment, can also be provided separately or in any suitable sub-combination. In the present detailed description, numerous specific details are set forth in order to provide a thorough understanding of the methods and apparatus.

It will also be understood that the system according to the present disclosure may be, at least partly, implemented on a suitably programmed computer. Likewise, the present disclosure contemplates a computer program being readable by a computer for executing the method of the present disclosure. The present disclosure further contemplates a non-transitory computer-readable memory tangibly embodying a program of instructions executable by the computer for executing the method of the present disclosure.

The present disclosure is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the presently disclosed subject matter.

Those skilled in the art will readily appreciate that various modifications and changes can be applied to the embodiments of the present disclosure as hereinbefore described without departing from its scope, defined in and by the appended claims.

1. A computerized system of runtime defect detection in a semiconductor specimen, the system comprising a processing circuitry configured to:
obtain a plurality of runtime images acquired for a plurality of dies on the specimen;
feed the plurality of runtime images to a plurality of input channels of a neural network (NN) in an input order, wherein the NN is previously trained in a training phase; and
process, by the NN, the plurality of runtime images simultaneously, to obtain a plurality of defect maps, each corresponding to a respective runtime image and indicating probabilities of defect candidate presence thereof, comprising, for each runtime image:
process the runtime image as a target image of a corresponding input channel that receives the runtime image, wherein remaining images in the plurality of runtime images are used as reference images of the target image; and
obtain a defect map of the target image which remains invariant, irrespective of changes to the input order.

2. The computerized system according to claim 1, wherein the NN comprises a plurality of hidden layers, each comprising a plurality of subsets of filters, each subset of filters in a given hidden layer corresponding to a specific input channel and usable for processing a target image or derivatives thereof of the specific input channel, wherein each subset of filters of the given hidden layer comprises a target filter to be applied to the target image or derivatives thereof, and reference filters to be applied to the reference images or derivatives thereof of the target image, the reference filters having the same values.

3. The computerized system according to claim 2, wherein the target filter across the plurality of subsets of filters in the given hidden layer, has the same value.

4. The computerized system according to claim 1, wherein the changes to the input order include at least one of: switching an order of the reference images, and switching an order of the target image and a reference image.

5. The computerized system according to claim 2, wherein the processing circuitry is configured to process the plurality of runtime images by: for each specific input channel of a given hidden layer, applying a given subset of filters corresponding to the specific input channel to the target image or derivatives thereof and the reference images or derivatives thereof, to obtain an output feature map serving as an input feature map of a subsequent hidden layer.

6. The computerized system according to claim 1, wherein the processing of the plurality of runtime images further comprises providing a background defect map, as part of output of the NN, indicating probability of defect absence in all of the plurality of dies.

7. The computerized system according to claim 1, wherein the plurality of defect maps are further reviewed by a review tool.

8. The computerized system according to claim 7, wherein one or more locations of false alarms and/or missed defect of interests (DOIs), identified during review, are re-examined, comprising: acquiring by an inspection tool one or more new images of the one or more locations, processing the one or more new images by the NN to obtain one or more new defect maps, and performing algorithmic analysis based on the new defect maps with respect to ground truth information of the locations provided by the review tool.

9. The computerized system according to claim 1, wherein the NN is a Convolutional Neural Network (CNN).

10. A computerized method of training a neural network (NN) usable for defect detection in a semiconductor specimen, the method comprising:
obtaining a plurality of training images acquired for a plurality of dies of a training specimen, each training image associated with a ground truth defect map indicative of defect spatial distribution in the training image;
feeding the plurality of training images to a plurality of input channels of the NN in an input order;
processing the plurality of training images by the NN simultaneously, to obtain, for each given training image, a predicted defect map indicating probabilities of defect candidate presence in the given training image;
optimizing the NN using a loss function based on the predicted defect map and the ground truth defect map associated with the given training image; and
repeating the feeding, processing, and optimizing until a criterion is met, thereby obtaining a trained NN usable to provide, for a plurality of runtime images, a plurality of defect maps invariant to changes to the input order of the plurality of runtime images to the trained NN.

11. The computerized method according to claim 10, wherein the NN comprises a plurality of hidden layers, each comprising a plurality of subsets of filters, each subset of filters in a given hidden layer corresponding to a specific input channel and usable for processing a target image or derivatives thereof of the specific input channel, wherein each subset of filters of the given hidden layer comprises a target filter to be applied to the target image or derivatives thereof, and reference filters to be applied to the reference images or derivatives thereof of the target image.

12. The computerized method according to claim 11, wherein the optimizing of the NN requires that the reference filters always have the same value.

13. The computerized method according to claim 12, wherein the optimizing of the NN requires that the target filter across the plurality of subsets of filters in the given hidden layer has the same value.

14. The computerized method according to claim 10, wherein the changes to the input order include at least one of: switching an order of the reference images, and switching an order of the target image and a reference image.

15. The computerized method according to claim 10, further comprising providing a background defect map, as part of output of the NN, indicating probability of absence of defect presence in all of the plurality of dies, and wherein the loss function is configured to enforce, based on the background defect map and the plurality of defect maps, a likelihood of a defect appearing at same location across the plurality of dies to be minimized.

16. A non-transitory computer readable storage medium tangibly embodying data representative of a neural network (NN) usable for defect detection in a semiconductor specimen, wherein the NN comprises:
an input layer having a plurality of input channels to respectively receive a plurality of runtime images in an input order;
a plurality of hidden layers, each comprising a plurality of subsets of filters, each subset of filters in a given hidden layer corresponding to a specific input channel and usable for processing a specific runtime image or derivatives thereof received in the specific input channel as a target image, wherein each subset of filters of the given hidden layer comprises a target filter to be applied to the target image or derivatives thereof, and reference filters to be applied to the reference images or derivatives thereof of the target image, the reference filters having the same values; and
an output layer to provide, for each runtime image of the plurality of runtime images, a defect map that remains invariant, irrespective of changes to the input order.

17. The non-transitory computer readable storage medium according to claim 16, wherein the target filter across the plurality of subsets of filters in the given hidden layer has the same value.

18. A non-transitory computer readable storage medium tangibly embodying a program of instructions that, when executed by a computer, cause the computer to perform a method of runtime defect detection in a semiconductor specimen, the method comprising:
obtaining a plurality of runtime images acquired for a plurality of dies on the specimen;
feeding the plurality of runtime images to a plurality of input channels of a neural network (NN) in an input order, wherein the NN is previously trained in a training phase; and
processing, by the NN, the plurality of runtime images simultaneously, to obtain a plurality of defect maps, each corresponding to a respective runtime image and indicating probabilities of defect candidate presence thereof, wherein each given runtime image is processed as a target image using remaining images in the plurality of runtime images as reference images of the target image, and the defect map of the target image remains invariant, irrespective of changes to the input order.

19. The non-transitory computer readable storage medium according to claim 18, wherein the NN comprises a plurality of hidden layers, each comprising a plurality of subsets of filters, each subset of filters in a given hidden layer corresponding to a specific input channel and usable for processing a specific runtime image or derivatives thereof received in the specific input channel as a target image, wherein each subset of filters of the given hidden layer comprises a target filter to be applied to the target image or derivatives thereof, and reference filters to be applied to the reference images or derivatives thereof of the target image, the reference filters having the same values.

20. The non-transitory computer readable storage medium according to claim 19, wherein the target filter across the plurality of subsets of filters in the given hidden layer has the same value.
